(19) United States
(12) Patent Application Publication
(10) Pub. No.: US 2020/0219737 A1
(43) Pub. Date: Jul. 9, 2020

(54) SEMICONDUCTOR PROCESSING CHAMBER

(71) Applicant: XIA TAI XIN SEMICONDUCTOR (QING DAO) LTD., Qingdao (CN)

(72) Inventors: KWANGI SEO, Singapore (SG); JEE-HOON KIM, Singapore (SG); KANG-WON SEO, Singapore (SG)

(21) Appl. No.: 16/679,323

(22) Filed: Nov. 11, 2019

Related U.S. Application Data
(60) Provisional application No. 62/778,965, filed on Dec. 13, 2018.

(51) Int. Cl. H01L 21/67; H01L 21/683; F16J 15/08

(52) U.S. Cl. CPC H01L 21/67017; F16J 15/0818; H01L 21/6831

(57) ABSTRACT

The instant disclosure includes a semiconductor processing chamber. The semiconductor processing chamber includes a lid, a body, and a gasket. The gasket has a sealing portion and at least one handle portion protruding from the sealing portion. The at least one handle portion is used for applying force to the gasket during replacement process.

### CROSS-REFERENCES TO RELATED APPLICATIONS

This application claims the benefit of U.S. Provisional Patent Application No. 62778965 filed on Dec. 13, 2018, which is hereby incorporated by reference herein and made a part of specification.

### BACKGROUND

### 1. Field

The present disclosure generally relates to semiconductor processing chamber, and more particularly, semiconductor processing chamber having a gasket with a handle portion.

### 2. Related Art

Some of the semiconductor processes may be operated in a chamber that is in a vacuum state, such as plasma processes. In many applications, gaskets are used to provide sealing between the chamber members to maintain vacuum state in a semiconductor processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a sectional view of a semiconductor processing chamber according to some embodiments of the instant disclosure;

FIG. 1B illustrates a cross sectional view of a gasket according to some embodiments of the instant disclosure;

FIG. 2A illustrates a sectional view of a semiconductor processing chamber according to some embodiments of the instant disclosure;

FIG. 2B illustrates a cross sectional view of a gasket according to some embodiments of the instant disclosure;

FIG. 3A illustrates a sectional view of a semiconductor processing chamber according to some embodiments of the instant disclosure;

FIG. 3B illustrates a cross sectional view of a gasket according to some embodiments of the instant disclosure;

FIG. 4 illustrates a cross sectional view of a gasket according to some embodiments of the instant disclosure;

FIG. 5-9 illustrates a sectional view of a gasket according to some embodiments of the instant disclosure; and

FIG. 10 illustrates a top view of a gasket according to some embodiments of the instant disclosure.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

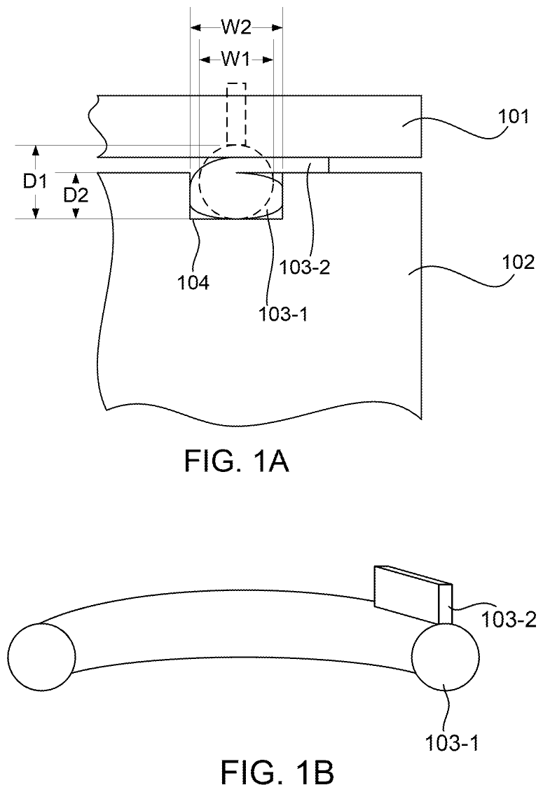

FIG. 1A illustrates a sectional view of a semiconductor processing chamber according to some embodiments of the instant disclosure. FIG. 1B illustrates a cross sectional view of a gasket according to some embodiments of the instant disclosure. The semiconductor processing chamber includes a lid 101, a body 102, and a gasket. The lid 101 has a top surface and a bottom surface opposite the top surface. The body 102 has a top surface mechanically attachable to the bottom surface the lid 101. The gasket has a sealing portion 103-1 and at least one handle portion 103-2 protruding from the sealing portion 103-1. In some embodiments, the top surface of the body 102 includes a channel 104 formed along a periphery of the body 102. In some embodiments, semiconductor processing chamber further comprises an electrostatic chuck disposed within the body 102 and configured to receive a substrate for processing.

The lid 101 is mechanically attached to the body 102 through vacuuming. The gap between the lid 101 and the body 102 may be sealed by the gasket. The material used to form the gasket may include an elastic material. The gasket may be compressed to form an airtight seal between the lid 101 and the body 102. In some embodiments, the channel 104 has a width W2 greater than a width W1 of a cross section of the gasket before compression. After compression, the width of a cross section of the gasket is equal to the width of the channel 104. The channel 104 has a depth D2 less than a thickness D1 of the cross section of the gasket before compression. After compression, the thickness of the cross section of the gasket may still be greater than the depth of the channel 104.

In some embodiments, the sealing portion 103-1 may comprise rubber. Rubber materials may selectively include fluorine rubber, fluoroelastomer, fluorinated rubber, fluorocarbon rubber, fluorine rubber. In some embodiments, the sealing portion 103-1 selectively comprises DuPont™ Kalrez® and DuPont™ Viton®.

In some embodiments, at least one handle portion 103-2 may comprise rubber. Rubber materials may selectively include fluorine rubber, fluoroelastomer, fluorinated rubber, fluorocarbon rubber, fluorine rubber. In some embodiments, the at least one handle portion 103-2 selectively comprises DuPont™ Kalrez® and DuPont™ Viton®.

In some embodiments, a material for the sealing portion 103-1 is different from a material of the at least one handle portion 103-2. In some other embodiments, a material for the sealing portion 103-1 is the same material as a material of the at least one handle portion 103-2. In some embodiments, the elasticity of the at least one handle portion 103-2 is less than the elasticity of sealing portion 103-1.

In some embodiments, the at least one handle portion 103-2 extends from a top surface of the sealing portion 103-1. Thus, the at least one handle portion 103-2 is compressed as well during mechanical attachment of the lid 101 and the body 102. When the gasket is pressed between the lid 101 and the body 102, a bottom surface of the at least one handle portion 103-2 becomes planar to the top surface of the body 102 and a top surface of the at least one handle portion 103-2 becomes planar to the bottom surface of the lid 101.

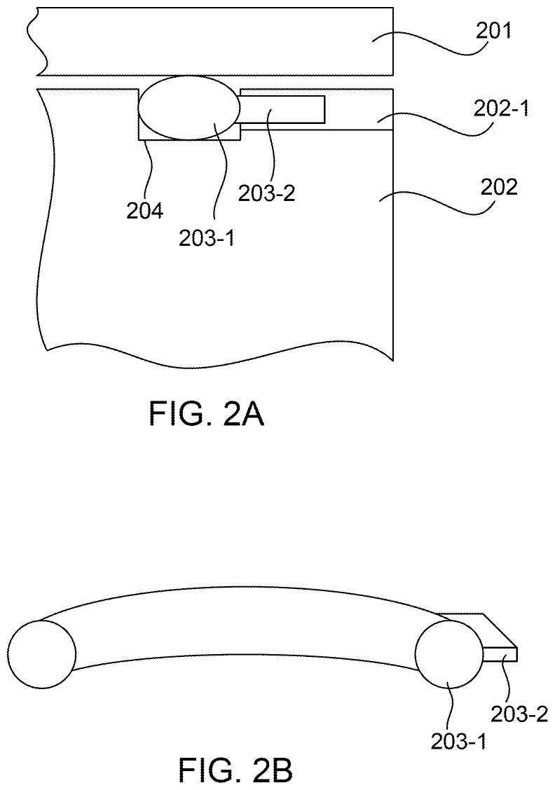

FIG. 2A illustrates a sectional view of a semiconductor processing chamber according to some embodiments of the instant disclosure. FIG. 2B illustrates a cross sectional view of a gasket according to some embodiments of the instant disclosure. The semiconductor processing chamber includes a lid 201, a body 202, and a gasket. The gasket has a sealing portion 203-1 and at least one handle portion 203-2 protruding from the sealing portion 203-1. In some embodiments, the top surface of the body 202 includes a channel 204. In some embodiments, the top surface of the body 202 further includes a notch 202-1 extending from the channel 204. In some embodiments, the at least one handle portion 203-2 extend from a side surface of the sealing portion 203-1. When the gasket is disposed into the channel 204, the at least one handle portion 203-2 is disposed within the notch 202-1. In some embodiments, a top surface of the at least one handle portion 203-2 is planar to the top surface of the body 202. In some other embodiments, as shown in FIG. 2A, a top surface of the at least one handle portion 203-2 is not planar to the top surface of the body 202.

The lid 201 is mechanically attached to the body 202 through vacuuming. The gap between the lid 201 and the body 202 may be sealed by the gasket. The material used to form the gasket may include an elastic material. The gasket may be compressed to form an airtight seal between the lid 201 and the body 202. After compression, the width of a cross section of the gasket is equal to the width of the channel 204 After compression, the thickness of the cross section of the gasket may still be greater than the depth of the channel. However, since the at least one handle portion 203-2 is disposed within the notch 202-1, the at least one handle portion 203-2 does not receive and force and does not compress.

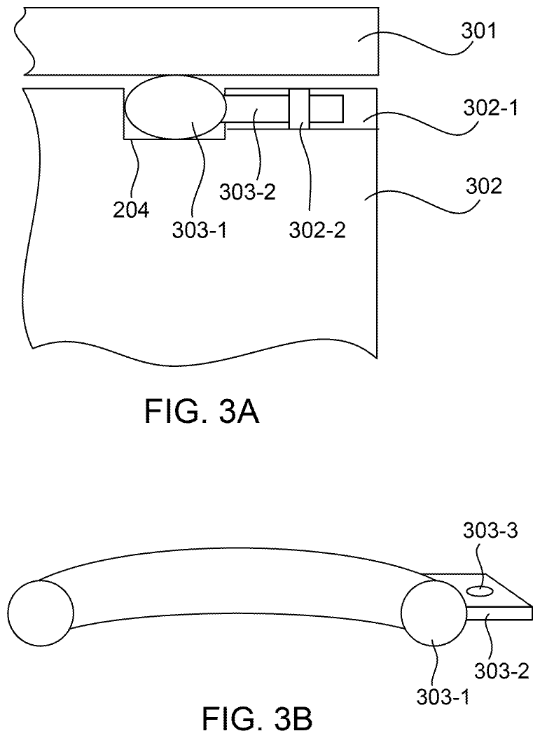

FIG. 3A illustrates a sectional view of a semiconductor processing chamber according to some embodiments of the instant disclosure. FIG. 3B illustrates a cross sectional view of a gasket according to some embodiments of the instant disclosure. The semiconductor processing chamber includes a lid 301, a body 302, and a gasket. The gasket has a sealing portion 303-1 and at least one handle portion 303-2 protruding from the sealing portion 303-1. In some embodiments, the top surface of the body 302 includes a channel 304. In some embodiments, the top surface of the body further includes a notch 302-1 extending from the channel 304. In some embodiments, the top surface of the body 302 further includes a pin portion 302-2 disposed within a periphery of the notch 302-1. In some embodiments, the at least one handle portion 303-2 has a hole 303-3 and the pin portion 302-2 penetrates through the hole 303-3.

The lid 301 is mechanically attached to the body 302 through vacuuming. The gap between the lid 301 and the body 302 may be sealed by the gasket. The material used to form the gasket may include an elastic material. The gasket may be compressed to form an airtight seal between the lid 301 and the body 302. After compression, the width of a cross section of the gasket is equal to the width of the channel 304 After compression, the thickness of the cross section of the gasket may still be greater than the depth of the channel. When the vacuum is released, the pin portion 302-2 may hold the gasket in place.

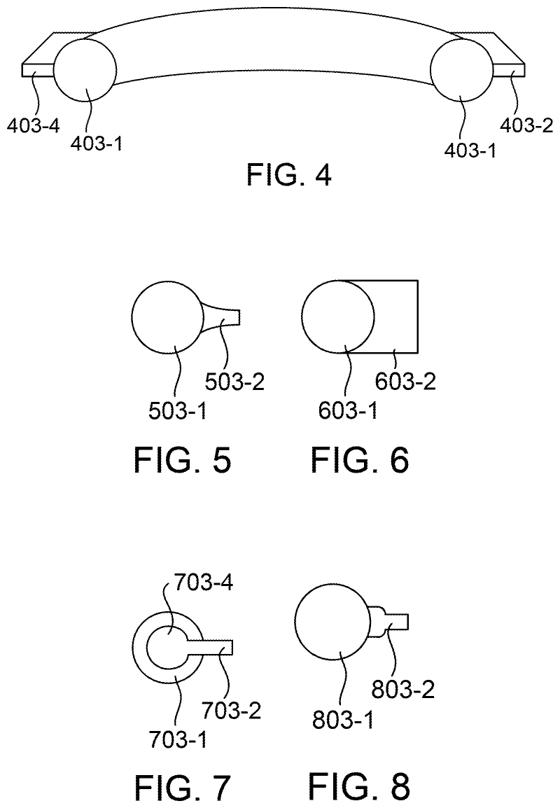

FIG. 4 illustrates a cross sectional view of a gasket according to some embodiments of the instant disclosure. The gasket has a sealing portion 403-1 and at least one handle portion 403-2 protruding from the sealing portion 403-1. In some embodiments, the at least one handle portion includes a first handle portion 403-2 and a second handle portion 403-4 opposite the first handle portion 403-2. In some embodiments, the body further includes another notch to accommodate the second handle portion 403-4.

FIG. 5 illustrates a sectional view of a gasket according to some embodiments of the instant disclosure. The gasket has a sealing portion 503-1 and at least one handle portion 503-2 protruding from the sealing portion 503-1. The at least one handle portion 503-2 is tapered in shape. The thickness of the at least one handle portion 503-2 decreases as the at least one handle portion 503-2 extends away from the periphery of the sealing portion 503-1.

FIG. 6 illustrates a sectional view of a gasket according to some embodiments of the instant disclosure. The gasket has a sealing portion 603-1 and at least one handle portion 603-2 protruding from the sealing portion 603-1. In some embodiments, the at least one handle portion 603-2 has a same thickness as the sealing portion 603-1. The gasket may be compressed to form an airtight seal between the lid and the body. Since the at least one handle portion 603-2 has a same thickness as the sealing portion 603-1, the at least one handle portion 603-2 is compressed as well during vacuumed state.

FIG. 7 illustrates a sectional view of a gasket according to some embodiments of the instant disclosure. The gasket has a sealing portion 703-1 and at least one handle portion 703-2 protruding from the sealing portion 703-1. In some embodiments, the gasket further comprises a core portion 703-4 disposed within the sealing portion 703-1. An elasticity of the sealing portion 703-1 is greater than an elasticity of the core portion 703-4. In some embodiments, the at least one handle portion 703-2 is the same material as the sealing portion 703-1. In some other embodiments, the at least one handle portion 703-2 is the same material as the core portion 703-4. In some embodiments, the core portion 703-4 is only disposed at a portion of the circumference of the gasket. In some other embodiments, the core portion 703-4 is disposed within the whole circumference of the gasket.

In some embodiments, the materials of core portion 703-4 may be elastomers (e.g., foam) wrapped or plated with conductive material. In some embodiments, the core portion 703-4 may comprise rigid metal that selectively comprise stainless steel (i.e. copper mix with nickel), copper, and chromium.

In some embodiments, the sealing portion 703-1 may comprise rubber. Rubber materials may selectively include fluorine rubber, fluoroelastomer, fluorinated rubber, fluorocarbon rubber, fluorine rubber. In some embodiments, the sealing portion 703-1 selectively comprises DuPont™ Kalrez® and DuPont™ Viton®.

FIG. 8 illustrates a sectional view of a gasket according to some embodiments of the instant disclosure. The gasket has a sealing portion 803-1 and at least one handle portion 803-2 protruding from the sealing portion 803-1. The thickness of the at least one handle portion 803-2 decreases as the at least one handle portion 803-2 extends away from the periphery of the sealing portion 803-1.

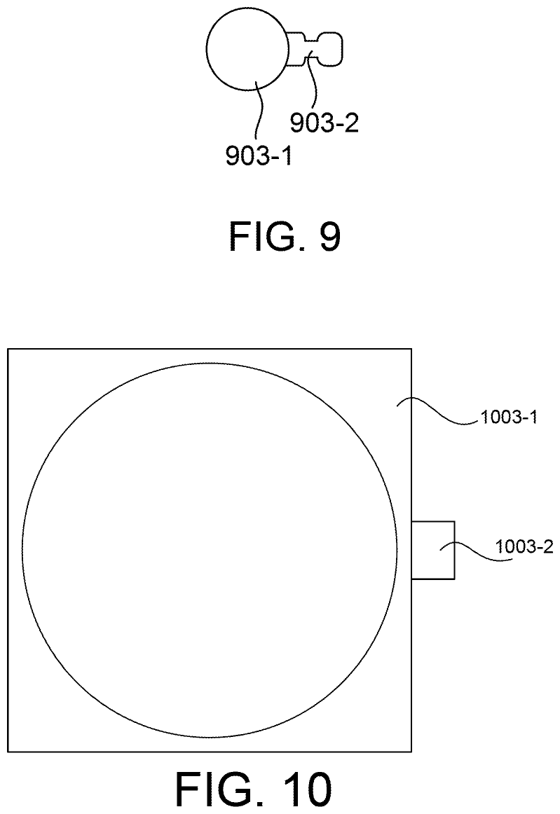

FIG. 9 illustrates a sectional view of a gasket according to some embodiments of the instant disclosure. The gasket has a sealing portion 903-1 and at least one handle portion 903-2 protruding from the sealing portion 903-1. To further improve the grip on the at least one handle portion 903-2, the thickness of the at least one handle portion 903-2 decreases as the at least one handle portion 903-2 extends away from the periphery of the sealing portion 903-1 and increases again at the portion farthest from the periphery of the sealing portion 903-1.

FIG. 10 illustrates a top view of a gasket according to some embodiments of the instant disclosure. The gasket has a sealing portion 1003-1 and at least one handle portion 1003-2 protruding from the sealing portion 1003-1. In some embodiments, an outer periphery of the sealing portion 1003-1 forms a rectangular shape and an inner periphery of the sealing portion 1003-1 forms a circular shape.

The embodiments disclosed in FIGS. 1A-10 are not limited thereto. The features of the disclosed embodiments may be mixed and matched to form a preferred structure of the gasket according to an application. The at least one handle portion of the gasket is used for applying force to the gasket during replacement process.

Accordingly, one aspect of the instant disclosure provides a semiconductor processing chamber that comprises a lid having a top surface and a bottom surface opposite the top surface; a body having a top surface mechanically attachable to the bottom surface the lid; and a gasket disposed between the lid and the body. The gasket has a sealing portion and at least one handle portion protruding from the sealing portion.

In some embodiments, semiconductor processing chamber further comprises an electrostatic chuck disposed within the body.

In some embodiments, the top surface of the body includes a channel having a width greater than a width of a cross section of the gasket before compression, and a depth less than a thickness of the cross section of the gasket before compression.

In some embodiments, the top surface of the body further includes a notch extending from the channel.

In some embodiments, the at least one handle portion is disposed within the notch.

In some embodiments, a top surface of the at least one handle portion is planar to the top surface of the body.

In some embodiments, the top surface of the body further includes a pin portion disposed within a periphery of the notch.

In some embodiments, the at least one handle portion has a hole and the pin portion penetrates through the hole.

In some embodiments, a bottom surface of the at least one handle portion is planar to the top surface of the body and a top surface of the at least one handle portion is planar to the bottom surface of the lid.

In some embodiments, a material for the sealing portion is different from a material of the at least one handle portion.

In some embodiments, the at least one handle portion includes a first handle portion and a second handle portion opposite the first handle portion.

Accordingly, another aspect of the instant disclosure provides a gasket for a semiconductor processing chamber that comprises a sealing portion having an elastic structure; and a handle portion protruding from the sealing portion.

In some embodiments, the gasket further comprises a core portion disposed within the sealing portion. An elasticity of the sealing portion is greater than an elasticity of the core portion.

In some embodiments, wherein the at least one handle portion includes a first handle portion and a second handle portion opposite the first handle portion.

In some embodiments, the at least one handle portion has a hole.

In some embodiments, an outer periphery of the sealing portion forms a rectangular shape and an inner periphery of the sealing portion forms a circular shape.

In some embodiments, a material for the sealing portion is different from a material of the at least one handle portion.

In some embodiments, the at least one handle portion has a same thickness as the sealing portion.

In some embodiments, the at least one handle portion extend from a top surface of the sealing portion.

In some embodiments, the at least one handle portion extend from a side surface of the sealing portion.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor processing chamber, comprising:
a lid having a top surface and a bottom surface opposite the top surface;
a body having a top surface mechanically attachable to the bottom surface the lid; and
a gasket disposed between the lid and the body;
wherein the gasket has a sealing portion and at least one handle portion protruding from the sealing portion.

2. The chamber in claim 1, further comprising:
an electrostatic chuck disposed within the body.

3. The chamber in claim 1, wherein the top surface of the body includes a channel having a width greater than a width of a cross section of the gasket before compression, and a depth less than a thickness of the cross section of the gasket before compression.

4. The chamber in claim 3, wherein the top surface of the body further includes a notch extending from the channel.

5. The chamber in claim 4, wherein the at least one handle portion is disposed within the notch.

6. The chamber in claim 5, wherein a top surface of the at least one handle portion is planar to the top surface of the body.

7. The chamber in claim 4, wherein the top surface of the body further includes a pin portion disposed within a periphery of the notch.

8. The chamber in claim 7, wherein the at least one handle portion has a hole and the pin portion penetrates through the hole.

9. The chamber in claim 1, wherein a bottom surface of the at least one handle portion is planar to the top surface of the body and a top surface of the at least one handle portion is planar to the bottom surface of the lid.

10. The chamber in claim 1, wherein a material for the sealing portion is different from a material of the at least one handle portion.

11. The chamber in claim 1, wherein the at least one handle portion includes a first handle portion and a second handle portion opposite the first handle portion.

12. A gasket for a semiconductor processing chamber, comprising:
a sealing portion having an elastic structure; and
a handle portion protruding from the sealing portion.

13. The gasket of claim 12, further comprising:
a core portion disposed within the sealing portion;
wherein an elasticity of the sealing portion is greater than an elasticity of the core portion.

14. The gasket of claim 12, wherein the at least one handle portion includes a first handle portion and a second handle portion opposite the first handle portion.

15. The gasket of claim 12, wherein the at least one handle portion has a hole.

16. The gasket of claim 12, wherein an outer periphery of the sealing portion forms a rectangular shape and an inner periphery of the sealing portion forms a circular shape.

17. The gasket of claim 12, wherein a material for the sealing portion is different from a material of the at least one handle portion.

18. The gasket of claim 12, wherein the at least one handle portion has a same thickness as the sealing portion.

19. The gasket of claim 12, wherein the at least one handle portion extends from a top surface of the sealing portion.

20. The gasket of claim 12, wherein the at least one handle portion extends from a side surface of the sealing portion.
